(19) United States
(12) Patent Application Publication
(10) Pub. No.: US 2026/0191025 A1
(43) Pub. Date: Jul. 2, 2026

(54) METHOD FOR MANUFACTURING WIRING STRUCTURE

(71) Applicant: Resonac Corporation, Minato-ku, Tokyo (JP)

(72) Inventor: Kei TOGASAKI, Minato-ku, Tokyo (JP)

(21) Appl. No.: 18/857,453

(22) PCT Filed: May 1, 2023
(86) PCT No.: PCT/JP2023/017056

§ 371 Date: Oct. 17, 2024

(51) Int. Cl. H10W 70/05; H05K 3/06; H10W 70/652

(52) U.S. Cl. CPC H10W 70/05; H05K 3/06; H10W 70/652

(57) ABSTRACT

A method of manufacturing a wiring structure by a novel wiring forming method includes forming a trench including a bottom surface including a surface of a substrate and a wall surface including a surface of a resist layer, forming a seed layer including an in-trench seed portion continuously formed from a position on the bottom surface to a position on the wall surface in the trench, forming a metal plating layer on the seed layer, the metal plating layer including a filling plating portion filling the trench together with the in-trench seed portion, and removing the resist layer so that wiring including the in-trench seed portion and the filling plating portion remains.

### TECHNICAL FIELD

The present disclosure relates to a method for manufacturing a wiring structure including a wiring layer.

### BACKGROUND ART

In a semiconductor device including a semiconductor element, a wiring structure including fine wiring such as a rewiring layer connected to the semiconductor element is provided in some cases. The wiring structure is formed by a semi-additive method including forming a resist layer having a pattern including an opening on a seed layer, forming an electrolytic plating layer on the seed layer in the opening, removing the resist layer, and removing an unnecessary portion of the seed layer by etching in some cases (for example, Patent Literature 1). As another method for forming the wiring layer, a trench method has been proposed in which an insulating layer forming the wiring layer is formed of a photosensitive resin material, and an electrolytic plating layer is formed in an opening of a patterned insulating layer by exposure and development (for example, Patent Literature 2).

### CITATION LIST

### Patent Literature

Patent Literature 1: Japanese Unexamined Patent Publication No. 2004-06773
Patent Literature 2: Japanese Unexamined Patent Publication No. 2018-85358

### SUMMARY OF INVENTION

### Technical Problem

The present disclosure relates to a novel method capable of manufacturing a wiring structure including a wiring layer including fine wiring with high accuracy.

### Solution to Problem

The present disclosure includes the following.

[1]

A method for manufacturing a wiring structure, the method including:
providing a resist layer on one main surface of a substrate;
patterning the resist layer by exposure and development to form a trench comprising a bottom surface including a surface of the substrate and a wall surface including a surface of the resist layer;
forming a seed layer comprising an in-trench seed portion continuously formed from a position on the bottom surface to a position on the wall surface in the trench, and an out-of-trench seed portion provided on a side opposite to the substrate of the resist layer and continuously formed with the in-trench seed portion;
forming a metal plating layer on the seed layer, the metal plating layer comprising a filling plating portion filling the trench together with the in-trench seed portion and a portion provided on the out-of-trench seed portion;
removing a part of the metal plating layer and the out-of-trench seed portion so that the resist layer is exposed and the filling plating portion remains; and
removing the resist layer from the main surface of the substrate so that wiring comprising the in-trench seed portion and the filling plating portion remains.
   [2]

The method according to [1], further including:
forming a barrier layer including a portion continuously formed from the position on the bottom surface to the position on the wall surface in the trench, in which
the seed layer is formed on the barrier layer, and
the resist layer is removed from the main surface of the substrate so that the barrier layer remains together with the wiring.
   [3]

The method according to [1] or [2], further including: forming an insulating layer surrounding the wiring on the main surface of the substrate, thereby forming a wiring layer comprising the wiring and the insulating layer.

[4]

The method according to [3], further including: stacking one or more additional wiring layers on a surface on a side opposite to the substrate of the wiring layer, the one or more additional wiring layers comprising additional wiring and an additional insulating layer surrounding the additional wiring.

### Advantageous Effects of Invention

A wiring structure including a wiring layer including fine wiring can be manufactured with high accuracy.

### BRIEF DESCRIPTION OF DRAWINGS

FIG. 1 is a process diagram illustrating an example of a method for manufacturing a wiring structure.

FIG. 2 is a process diagram illustrating an example of a method for manufacturing a wiring structure.

FIG. 3 is a process diagram illustrating an example of a method for manufacturing a wiring structure.

FIG. 4 is a process diagram illustrating an example of a method for manufacturing a wiring structure.

FIG. 5 is an electron microscope picture of an intermediate structure after a trench and a seed layer are formed.

FIG. 6 is an electron microscope picture of an intermediate structure after a metal plating layer is formed.

FIG. 7 is an electron microscope picture of formed wiring.

### DESCRIPTION OF EMBODIMENTS

The present invention is not limited to the following examples.

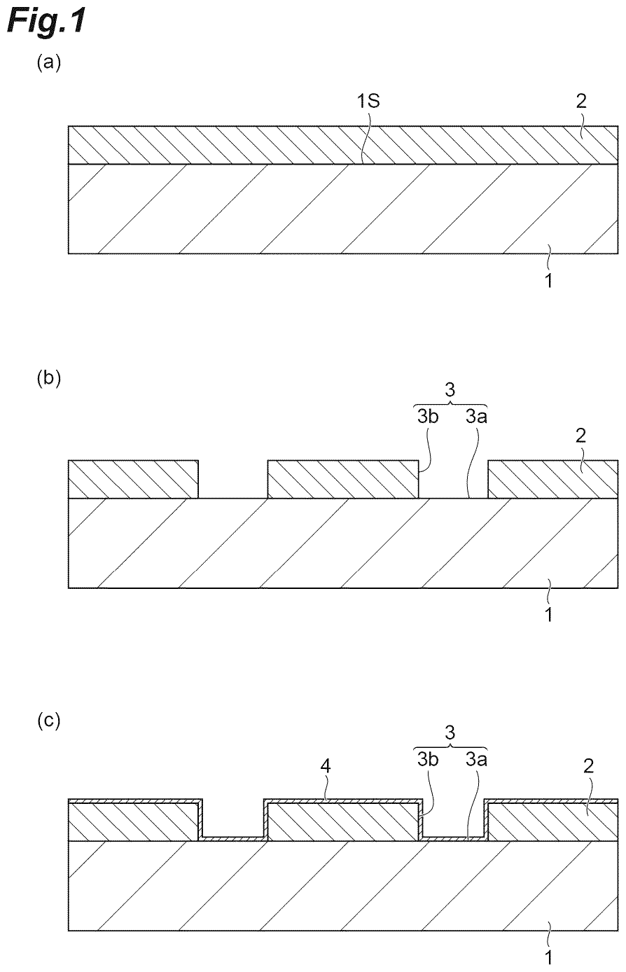

FIGS. 1, 2, and 3 are process diagrams illustrating an example of a method of manufacturing a wiring structure including a wiring layer. A method illustrated in FIGS. 1 to 3 includes preparing a substrate 1, providing a resist layer 2 on one main surface 1S of the substrate 1, patterning the resist layer 2 by exposure and development, thereby forming a trench 3 in which the substrate 1 is exposed, forming a barrier layer 4 covering the substrate 1 and the resist layer 2, forming a seed layer 5 on the barrier layer 4, forming a metal plating layer 6 on the seed layer 5, removing a part of the metal plating layer 6, the seed layer 5, and the barrier layer 4, thereby exposing the resist layer 2, and removing the resist layer 2 from the main surface 1S of the substrate 1 in such a manner that wiring 11 including the seed layer 5 and the metal plating layer 6 remains.

The substrate 1 may be a temporary support for forming the wiring structure, or may be a member including a circuit to which the wiring in the wiring structure is connected. For example, the substrate 1 may be a member including a semiconductor element, and the wiring structure may be a rewiring layer connected to the semiconductor element. In this case, the method according to the present disclosure can be used, for example, for manufacturing a fan-out type semiconductor package including the semiconductor element and the rewiring layer. By the method according to the present disclosure, it is also possible to manufacture an interposer that is a wiring structure for connecting semiconductor elements in a semiconductor package such as so-called 2.5D, 2.3D, or 2.1D.

The resist layer 2 can be formed of a resist material usually used for forming the wiring and the like. The resist layer 2 may be provided on the main surface 1S by stacking a dry film resist. Alternatively, the resist layer 2 may be formed by a method including applying a liquid resist on the main surface 1S and drying a coating film.

A resist material for forming the resist layer 2 is removed after a metal plating layer for wiring is formed, and is not used as a material for forming an insulating layer forming the wiring layer. Therefore, it is not necessary to take performance as the insulating layer into consideration, and the resist material can be selected mainly on the basis of performance as a photosensitive material.

As illustrated in FIG. 1(b), by patterning the resist layer 2 by a normal method including exposure and subsequent development, the trench 3 in which the substrate 1 is exposed can be formed. The trench 3 includes a bottom surface 3a including a surface (main surface 1S) of the substrate 1 and a wall surface 3b including a surface (side surface) of the resist layer 2, and extends in an in-plane direction of the main surface 1S of the substrate 1. The trench 3 includes a portion corresponding to a position in which wiring is formed. A plurality of trenches 3 may be independently provided on the main surface 1S. A minimum width of the trench 3 may be, for example, 0.5 μm or more and 10 μm or less. A minimum interval between the trenches 3 may be, for example, 0.5 μm or more and 10 μm or less. A depth of the trench 3 (or a thickness of the resist layer 2) may be, for example, 1 μm or more and 15 μm or less. The minimum width of the trench 3 can be a minimum value of a width in a direction perpendicular to a longitudinal direction of the trench 3.

As illustrated in FIG. 1(c), the barrier layer 4 includes a portion continuously formed from a position on the bottom surface 3a to a position on the wall surface 3b in the trench 3, and a portion provided on a surface opposite to the substrate 1 of the resist layer 2. In the trench 3, the barrier layer 4 forms a trench or a recess having a shape corresponding to the trench 3. The barrier layer 4 is a layer provided mainly for suppressing migration from the wiring, and is interposed between the wiring 11 to be formed and the substrate 1 and resist layer 2. The barrier layer 4 can be a layer containing titanium, for example. A thickness of the barrier layer 4 may be 10 nm or more and 50 nm or less, for example. The barrier layer 4 can be formed by a sputtering method, for example. The barrier layer 4 is not necessarily provided.

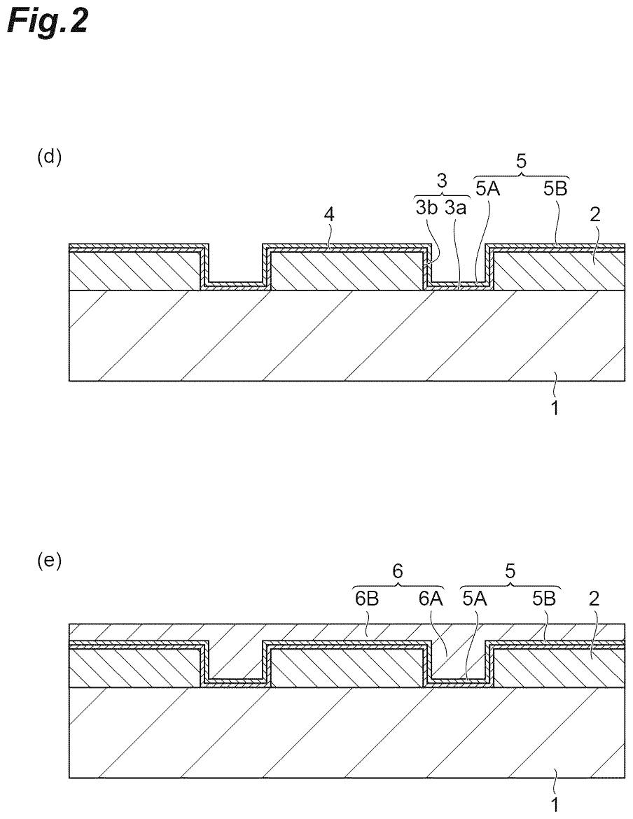

As illustrated in FIG. 2(d), the seed layer 5 formed on the barrier layer 4 includes an in-trench seed portion 5A continuously formed from the position on the bottom surface 3a to the position on the wall surface 3b in the trench 3, and an out-of-trench seed portion 5B provided on a side opposite to the substrate 1 of the resist layer 2. The out-of-trench seed portion 5B is formed continuously from the in-trench seed portion 5A. The seed layer 5 is used for forming the metal plating layer 6 by electrolytic plating. The seed layer 5 can be a layer containing metal such as copper. A thickness of the seed layer may be 50 nm or more and 500 nm or less, for example. Since the seed layer is not provided between the substrate 1 and the resist layer 2, etching for removing an unnecessary seed layer and the like after the resist layer 2 is removed is not required. Therefore, a decrease in width of the wiring 11 due to etching can be avoided. A portion covering a side surface of the wiring 11 of the barrier layer 4 can be easily left. The seed layer 5 can be formed by, for example, a sputtering method. The seed layer 5 may be formed by electroless plating.

As illustrated in FIG. 2(e), the metal plating layer 6 is formed on the seed layer 5 by electrolytic plating. The metal plating layer 6 includes a filling plating portion 6A that fills the trench 3 together with the in-trench seed portion 5A of the seed layer 5 and the barrier layer 4, and a portion provided on the out-of-trench seed portion 5B of the seed layer 5. The metal plating layer 6 is usually formed so as to cover an entire surface on a side opposite to the substrate 1 of the seed layer 5. The metal plating layer 6 can be a layer containing copper. A surface on a side opposite to the substrate 1 of the metal plating layer 6 may be flat or may have irregularities formed thereon. A thickness (thickness in a thickness direction of the substrate 1) of the filling plating portion 6A in the metal plating layer 6 may be 1 μm or more and 15 μm or less. A thickness of a portion provided on the out-of-trench seed portion 5B in the metal plating layer 6 may be 0.1 μm or more and 5 μm or less.

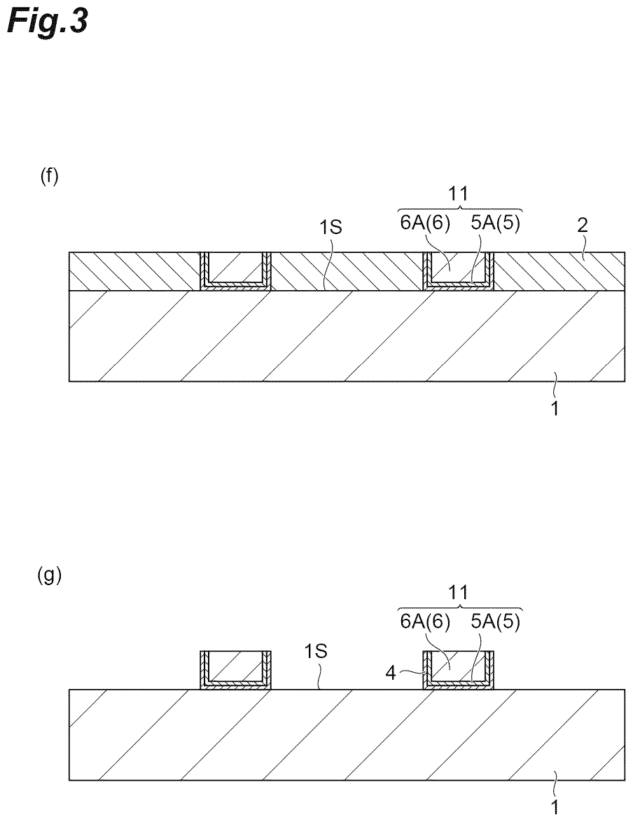

After the metal plating layer 6 is formed, as illustrated in FIG. 3(f), a part of the metal plating layer 6, the out-of-trench seed portion 5B in the seed layer 5, and a part of the barrier layer 4 are removed so that the resist layer 2 is exposed and the filling plating portion 6A remains. The metal plating layer 6, the seed layer 5, and the barrier layer 4 can be removed by, for example, etching or chemical mechanical polishing (CMP). As a result of the removal, a flat surface including the surface of the resist layer 2 and the remaining surface of the filling plating portion 6A may be formed.

Subsequently, as illustrated in FIG. 3(g), the resist layer 2 is removed from the main surface 1S of the substrate 1 in such a manner that the wiring 11 including the in-trench seed portion 5A and the filling plating portion 6A remains. Usually, together with the wiring 11, the barrier layer 4 including a portion covering the side surface thereof is also left. The resist layer 2 can be removed by, for example, dissolution into a peeling solution.

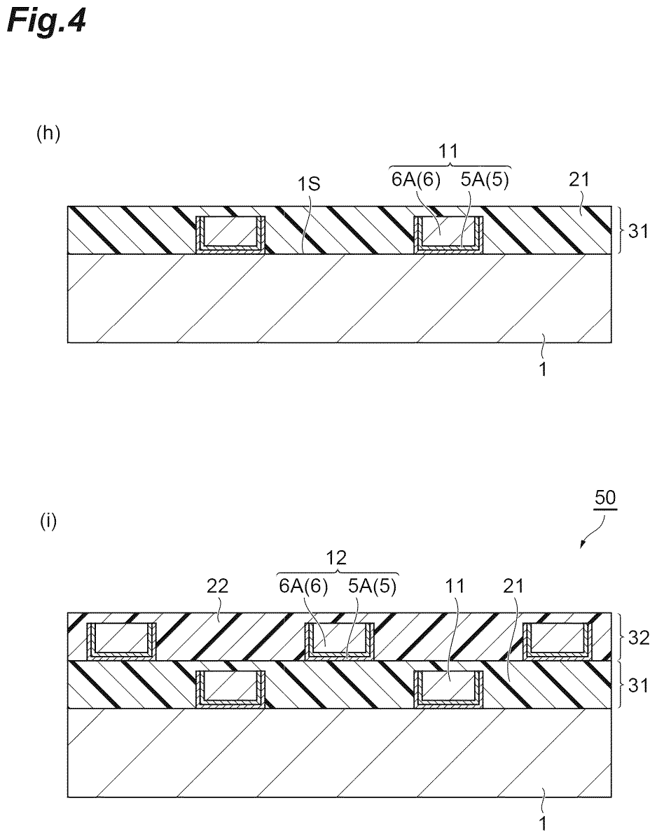

After the resist layer 2 is removed, as illustrated in FIG. 4(h) an insulating layer 21 surrounding the wiring 11 may be formed on the main surface 1S of the substrate 1. As a result, the wiring layer 31 including the wiring 11 and the insulating layer 21 is formed. The insulating layer 21 may be an insulating resin layer. For example, the insulating layer 21 may contain polybenzoxazole, polyimide, or a combination thereof. A part of or an entire main surface 1S of the substrate 1 may be a surface of an insulating layer similar to the insulating layer 21.

As illustrated in FIG. 4(i), an additional wiring layer 32 including additional wiring 12 and an additional insulating layer 22 surrounding the additional wiring 12 may be further stacked on a surface on a side opposite to the substrate 1 of the wiring layer 31. The additional wiring 12 may be formed in a manner similar to that of the wiring 11, and in this case, the additional wiring 12 may also include the in-trench seed portion 5A of the seed layer 5 and the filling plating portion 6A of the metal plating layer 6. The additional insulating layer 22 can be a layer similar to the insulating layer 21. By stacking one or more additional wiring layers in a manner similar to the method exemplified regarding the wiring layer 31, a wiring structure 50 including a multiple wiring layers can be formed. A multilayer structure including a plurality of wiring layers may include vias that connect the wiring layers.

### EXAMPLES

Hereinafter, an example of forming a wiring layer by the method according to the present disclosure will be described. The present invention is not limited to the following examples.

A liquid resist was applied onto a main surface of a substrate including a surface containing a polyimide resin, and a coating film was dried to form a resist layer. The resist layer was patterned by exposure to ultraviolet rays and subsequent development to form a plurality of linear trenches extending on the main surface of the substrate. The trench included a bottom surface including a surface of the substrate and a wall surface including a surface of the resist layer. A maximum width of each trench and an interval between adjacent trenches were approximately 5 μm.

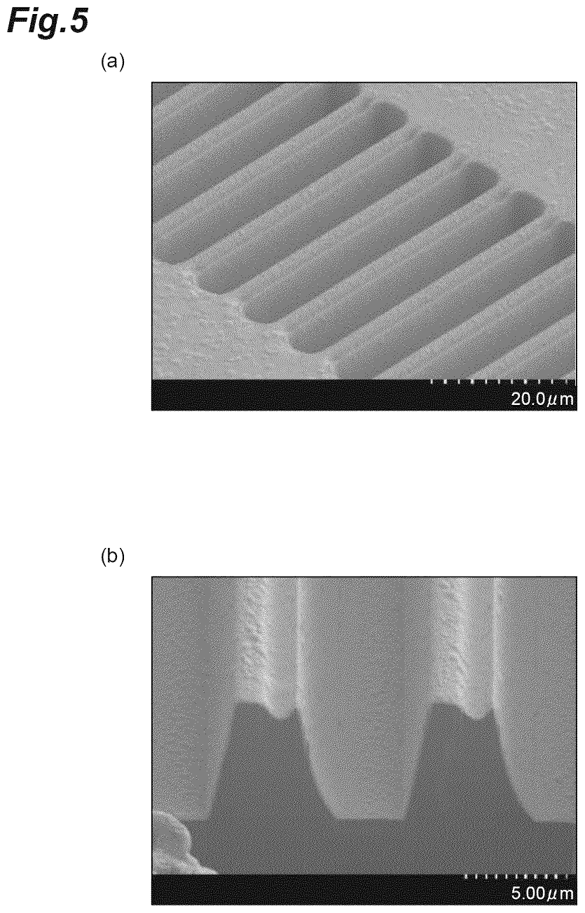

A Cu film covering the bottom surface and wall surface in the trench and a surface on a side opposite to the substrate of the resist layer was formed as a seed layer by a sputtering method. FIG. 5 is an electron microscope picture of an intermediate structure after the trench and seed layer are formed. The picture in FIG. 5(b) has a cross-section perpendicular to a longitudinal direction of the trench. The formed seed layer included an in-trench seed portion continuously formed from the bottom surface to the wall surface in the trench, and an out-of-trench seed portion provided on a side opposite to the substrate of the resist layer and formed continuously from the in-trench seed portion.

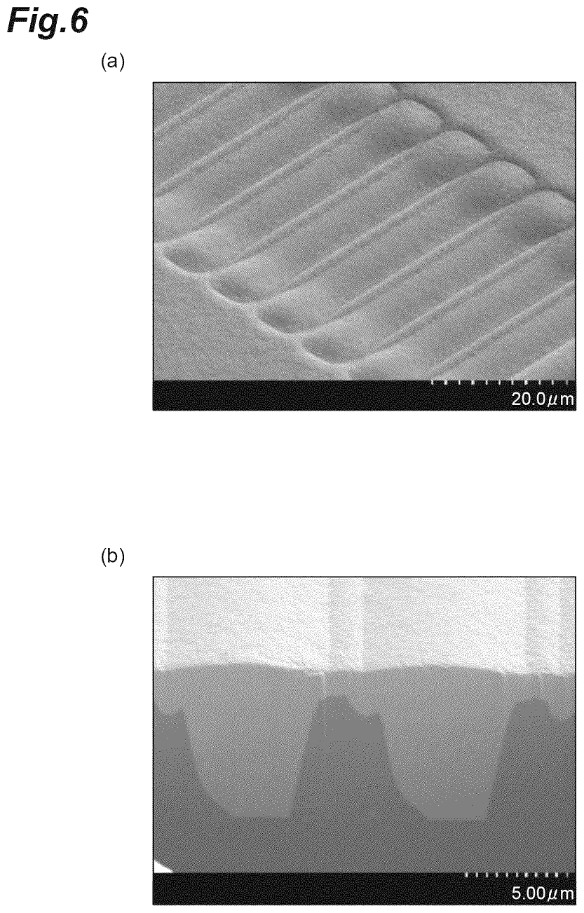

Subsequently, a metal plating layer (copper plating layer) was formed on the seed layer by electrolytic copper plating. FIG. 6 is an electron microscope picture of an intermediate structure including a metal plating layer. The picture in FIG. 6(b) has a cross-section perpendicular to a longitudinal direction of the trench. The metal plating layer included a filling plating portion that fills the trench together with the in-trench seed portion, and a portion provided on the out-of-trench seed portion.

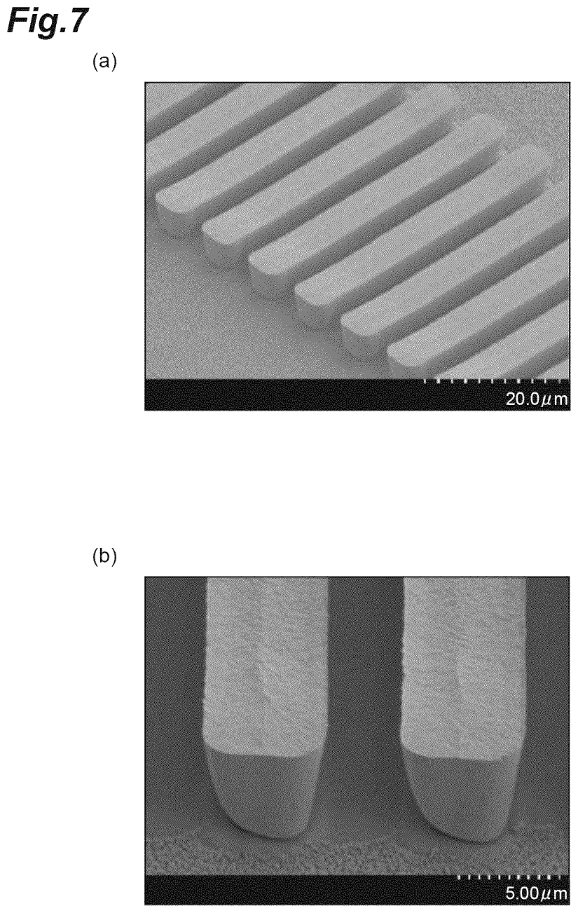

A part of the metal plating layer and the out-of-trench seed portion in the seed layer were removed by etching to form a flat surface formed of the exposed resist layer and a remaining metal plating layer (filling plating portion). Thereafter, the resist layer was removed by dissolution into a peeling solution. FIG. 7 is an electron microscope picture of a wiring layer including a metal plating layer (filling plating portion) remaining on a substrate. It was confirmed that the wiring having an excellent shape was formed with high accuracy. When wiring was formed in a procedure similar to that described above except that the maximum width of each trench and the interval between the adjacent trenches were changed to approximately 3 μm or approximately 2 μm, wiring having an excellent shape was formed with high accuracy in any case.

### REFERENCE SIGNS LIST

1 Substrate
2 Resist layer
3 Trench
3a Bottom surface
3b Wall surface
4 Barrier layer
5 Seed layer
5A In-trench seed portion
5B Out-of-trench seed portion
6 Metal plating layer
6A Filling plating portion
11, 12 Wiring
21, 22 Insulating layer
31, 32 Wiring layer
50 Wiring structure

1. A method for manufacturing a wiring structure, the method comprising:
providing a resist layer on one main surface of a substrate;
patterning the resist layer by exposure and development to form a trench comprising a bottom surface including a surface of the substrate and a wall surface including a surface of the resist layer;
forming a seed layer comprising an in-trench seed portion continuously formed from a position on the bottom surface to a position on the wall surface in the trench, and an out-of-trench seed portion provided on a side opposite to the substrate of the resist layer and continuously formed with the in-trench seed portion;
forming a metal plating layer on the seed layer, the metal plating layer comprising a filling plating portion filling the trench together with the in-trench seed portion and a portion provided on the out-of-trench seed portion;
removing a part of the metal plating layer and the out-of-trench seed portion so that the resist layer is exposed and the filling plating portion remains; and
removing the resist layer from the main surface of the substrate so that wiring comprising the in-trench seed portion and the filling plating portion remains.

2. The method according to claim 1, further comprising:
forming a barrier layer comprising a portion continuously formed from the position on the bottom surface to the position on the wall surface in the trench, wherein
the seed layer is formed on the barrier layer, and
the resist layer is removed from the main surface of the substrate so that the barrier layer remains together with the wiring.

3. The method according to claim 1, further comprising: forming an insulating layer surrounding the wiring on the main surface of the substrate, thereby forming a wiring layer comprising the wiring and the insulating layer.

4. The method according to claim 3, further comprising: stacking one or more additional wiring layers on a surface on a side opposite to the substrate of the wiring layer, the one or more additional wiring layers comprising additional wiring and an additional insulating layer surrounding the additional wiring.
